(19) United States
(12) Patent Application Publication
(10) Pub. No.: US 2026/0259508 A1
(43) Pub. Date: Sep. 3, 2026

(54) SEMICONDUCTOR SUBSTRATE HAVING A HYBRID ALIGNMENT STRUCTURE

(71) Applicant: Infineon Technologies AG, Neubiberg (DE)

(72) Inventor: Joerg Ortner, Drobollach am Faakersee (AT)

(21) Appl. No.: 19/539,688

(22) Filed: Feb. 13, 2026

(30) Foreign Application Priority Data
Feb. 28, 2025 (DE) 102025107704.5

(51) Int. Cl. G03F 7/00; G03F 9/00

(52) U.S. Cl. CPC G03F 7/70633; G03F 9/7003; G03F 9/7076

(57) ABSTRACT

A semiconductor substrate includes an alignment mark and a base layer. The base layer includes a first sub-structure of the alignment mark and a second sub-structure of the alignment mark. The first sub-structure is formed by a first mask-and-exposure lithography process and the second sub-structure is formed by a second mask-and-exposure lithography process. The semiconductor substrate further includes a structured layer disposed over the base layer. The first sub-structure and the second sub-structure are configured to provide alignment information for alignment of the structured layer.

### TECHNICAL FIELD

This disclosure relates to the field of semiconductor substrate processing, and in particular to the technique of manufacturing a semiconductor substrate having an alignment structure.

### BACKGROUND

The fabrication of semiconductor devices typically comprises a sequence of photolithography steps. Alignment structures are necessary to align different lithographic layers in production.

In the course of lithographic resist patterning, layers are aligned according to a so called “alignment tree”. After lithography resist patterning, overlay measurements are performed for pairs of layers.

More specifically, in alignment processes, an align-to layer having an alignment mark is used to independently align subsequent layers to this common align-to layer. In overlay measurements, the overlay errors between a base layer having a first overlay measurement mark and individual subsequent layers each having individual second overlay measurement marks are measured.

### SUMMARY

According to an aspect of the disclosure, a semiconductor substrate, which comprises an alignment mark, comprises a base layer. The base layer comprises a first sub-structure of the alignment mark and a second sub-structure of the alignment mark. The first sub-structure is formed by a first mask-and-exposure lithography process and the second sub-structure is formed by a second mask-and-exposure lithography process. The semiconductor substrate further comprises a structured layer disposed over the base layer, wherein the first sub-structure and the second sub-structure are configured to provide alignment information for alignment of the structured layer.

According to an aspect of the disclosure a method of manufacturing a semiconductor substrate comprising an alignment mark comprises forming a first sub-structure of the alignment mark in a base layer of the semiconductor substrate by a first mask-and-exposure lithography process. A second sub-structure of the alignment mark in the base layer is formed by a second mask-and-exposure lithography process. A layer is formed over the base layer. The layer is structured based on alignment information from the first sub-structure and alignment information from the second sub-structure.

According to an aspect of the disclosure, a semiconductor substrate, which comprises a primary overlay measurement mark and a secondary overlay measurement mark, comprises a base layer. The base layer comprises a first sub-structure of the primary overlay measurement mark and a second sub-structure of the primary overlay measurement mark. The first sub-structure is formed by a first mask-and-exposure lithography process and the second sub-structure is formed by a second mask-and-exposure lithography process. The substrate further comprises a structured layer disposed over the base layer, the structured layer comprising the secondary overlay measurement mark.

According to an aspect of the disclosure, a method of performing an overlay error measurement on a semiconductor substrate, which comprises a primary overlay measurement mark and a secondary overlay measurement mark, comprises forming a first sub-structure of the primary overlay measurement mark in a base layer of the semiconductor substrate by a first mask-and-exposure lithography process. A second sub-structure of the primary overlay measurement mark is formed in the base layer by a second mask-and-exposure lithography process. A layer is formed over the base layer, the layer comprising the secondary overlay measurement mark. The primary overlay measurement mark and the secondary overlay measurement mark are optically recognized to provide a first signal based on the contrast of the primary overlay measurement mark and a second signal based on the contrast of the secondary overlay measurement mark. The first signal and the second signal are evaluating to obtain a set of overlay error parameters.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIGS. 1A illustrates an alignment tree showing lithography processes for conventional layer alignment.

FIG. 1B illustrates an exemplary layer stack of a semiconductor substrate processed by the lithography alignment scheme of FIG. 1A.

FIGS. 2A illustrates an alignment tree showing lithography processes in accordance with the disclosure.

FIG. 2B illustrates an exemplary layer stack of a semiconductor substrate processed by the lithography alignment scheme of FIG. 2A.

FIG. 3 is a schematic top view on a semiconductor substrate illustrating a number of alignment marks, active component zones and a grid for exposure.

FIG. 4 illustrates an alignment mark and a signal based on the contrast of the alignment mark.

FIG. 5A illustrates two examples of an alignment mark formed by a first mask-and-exposure lithography process in a first layer.

FIG. 5B illustrates two examples of an alignment mark formed by a second mask-and-exposure lithography process in, e.g., a second layer.

FIG. 5C illustrates two examples of a hybrid alignment mark formed by two mask-and-exposure lithography processes in a first and, e.g., a second layer.

FIG. 6 illustrates examples of conventional alignment marks formed by subsequent lithography processes in subsequent layers and an example of a hybrid alignment mark having sub-structures from both lithography processes.

FIG. 7 is a schematic sectional view showing an exemplary semiconductor device fabricated in accordance with the disclosure.

FIG. 8 is a schematic illustration of a process flow for manufacturing a semiconductor substrate.

FIG. 9 is a top view on an example of a primary and a secondary overlay measurement mark formed in a semiconductor substrate.

FIG. 10 is a schematic illustration of a process flow illustrating an overlay error feedback control loop for stabilizing the overlay error during manufacturing of a plurality of semiconductor substrates.

FIG. 11 is a top view on an example of a primary hybrid overlay measurement mark and a secondary overlay measurement mark, wherein the primary hybrid overlay measurement mark is formed by two mask-and-exposure lithography processes in the semiconductor substrate in accordance with the disclosure.

### DETAILED DESCRIPTION

The words “over” or “beneath” and similar words with regard to a part, element or material layer formed or located “over” or “beneath” a surface may be used herein to mean that the part, element or material layer be located (e.g. placed, formed, arranged, deposited, etc.) “directly on” or “directly under”, e.g. in direct contact with, the implied surface. The word “over” or “beneath” and similar words used with regard to a part, element or material layer formed or located “over” or “beneath” a surface may, however, either be used herein to mean that the part, element or material layer be located (e.g. placed, formed, arranged, deposited, etc.) “indirectly on” or “indirectly under” the implied surface, with one or more additional parts, elements or layers being arranged between the implied surface and the part, element or material layer.

During semiconductor processing and semiconductor device manufacturing, proper alignment of functional structures generated by a plurality of mask-and-exposure lithography processes (referred to in the following as “lithography”) is of importance. Functional structures are, for example, trenches, contacts, insulating structures etc. Such functional structures, which should be aligned as well as possible with each other, may be formed in different layers of the semiconductor substrate or in the same layer by different lithography processes.

As known in the art, at least two approaches are commonly used to minimize misalignment of functional structures. Alignment marks are used to align the lithography exposure tool (e.g., stepper or scanner) relative to the substrate. Overlay measurement marks are used to measure an overlay error between successive layers. Both approaches rely on optically recognizing the respective mark to provide a signal based on the contrast of the mark and to evaluating the signal to obtain a precise position of the mark.

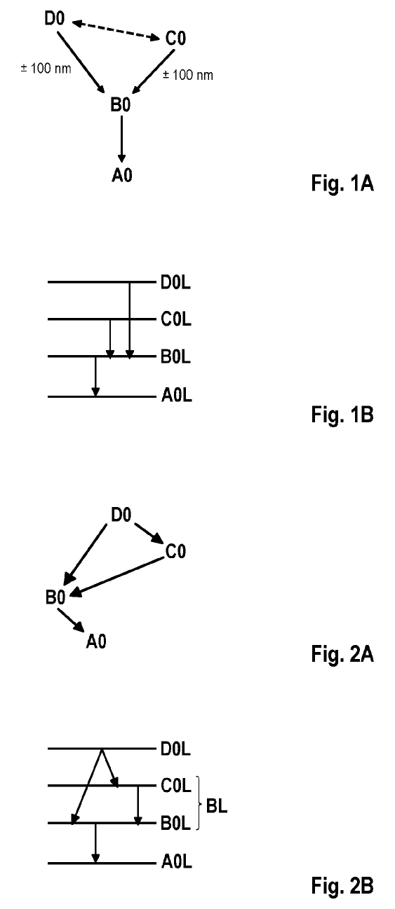

FIG. 1A illustrates an alignment tree conventionally used for aligning a semiconductor substrate during various manufacturing steps. Solid arrows indicate direct alignment processes. B0 relates to an “align-to” lithography process. D0 and C0 each relate to lithography processes which are aligned independently to B0. In other words, an alignment mark produced by lithography process B0 is used as an alignment reference for the lithography process C0 and for the lithography process D0. The “align-to” lithography process B0 may, e.g., itself be aligned to an earlier lithography process A0.

As a result, D0 may be misaligned to B0 in opposite direction compared to C0, as D0 has no knowledge about any potential misalignment of C0 relative to B0. For example, if each direct alignment process (solid arrows) is subjected to alignment tolerances of ±100 nm, D0 may, e.g., be “indirectly” misaligned to C0 by ±200 nm at worst.

FIG. 1B illustrates an example of a layer structure of a semiconductor substrate on which the alignment tree of FIG. 1A can be mapped. For ease of notation, the possible layers are denoted by similar reference signs A0L, B0L, C0L, D0L as used in FIG. 1A for lithography processes A0, B0, C0, D0 exercised on the corresponding layers A0L, B0L, C0L and D0L, respectively.

For example, A0L may refer to a bulk body of the semiconductor substrate (wafer). A bulk body of a semiconductor substrate may include or be of silicon (Si) or group IV compound semiconductor materials such as silicon carbide (SiC) or silicon germanium (SiGe). The bulk body may, e.g., include or be of type III-V semiconductor materials including gallium nitride (GaN), gallium arsenide (GaAs), aluminum nitride (AlN), aluminum arsenide (AlAs), indium nitride (InN), indium arsenide (InAs), etc. Generally, the bulk body may be of any semiconductor material used in device manufacturing by semiconductor processing.

B0L may refer to a layer disposed over layer A0L. For example, layer B0L may, e.g., be a trench layer, i.e. a layer in which trenches are formed by lithography B0. Trenches are known as examples of functional structures in semiconductor technology, e.g. as structures used in trench transistors or trench capacitors, etc.

Further, an alignment mark may be formed in layer B0L by the same lithography process B0 as used for forming the functional structures (e.g. trenches) in layer B0. For example the layer B0L may, e.g., be an epitaxial layer such as, e.g., a doped silicon epitaxial layer.

Layer C0L is disposed over layer B0L. The layer C0L is aligned to the “align-to” layer B0L by using the alignment mark(s) formed in layer B0L during the lithography process B0.

The layer C0L is directly aligned to the “align-to” layer B0L by lithography C0 using the alignment mark in layer B0L. For example, layer C0L may, e.g., be a polysilicon layer used for functional polysilicon structures in the semiconductor substrate, e.g., for gate polysilicon structures of transistors.

Reference sign D0L refers to a layer disposed over the layer C0L. Layer D0L is directly aligned to “align-to” layer B0L by using alignment mark(s) formed during lithography B0. For example, layer D0L may, e.g., be a contact layer, for example a metal layer used for contacting functional structures in layer C0L and functional structures in layer B0L.

That is, as an example, the layer D0L may implement contacts to the functional polysilicon structures in the second layer C0L and contacts to the trenches in the first layer B0L. Conventionally, lithography D0 (and thus, the contacts) can only be aligned to the first layer B0L (see, e.g., FIG. 1A) or the second layer C0L, leading to “indirect” misaligned to the other layer by, e.g., ±200 nm at worst.

FIGS. 2A and 2B illustrate exemplary alignment of lithography processes A0, B0, C0, D0 and layers A0L, B0L, C0L, D0L in accordance with the disclosure. The lithography alignment scheme explained by FIGS. 2A and 2B uses a so-called hybrid alignment mark which includes alignment information of at least two lithography processes, e.g. the lithography process B0 and the lithography process C0.

More specifically, a lithography process A0 may be performed on the semiconductor substrate. The lithography process A0 may, e.g., be used for structuring the layer A0L. As mentioned above, layer A0L may refer to the bulk body of the semiconductor substrate.

A first sub-structure of the hybrid alignment mark is formed by a first lithography process B0. A second sub-structure of the hybrid alignment mark is formed by a second lithography process C0. The lithography processes B0 and C0 are different lithography processes. They may, e.g., be independent of each other.

For example, the first lithography process B0 may be aligned to A0. The second lithography process C0 may, e.g., be aligned to B0, for example.

The first lithography process B0 may be used to process the first layer B0L and the second lithography process C0 may be used to process a second layer C0L. However, it is also possible that B0 and C0 are used to process the same layer, which is indicated in FIG. 2B as base layer BL. In this case, the first sub-structure of the hybrid alignment mark produced by B0 and the second sub-structure of the hybrid alignment mark produced by C0 are formed in the same layer, namely the base layer BL (in which B0L and C0L then fall together).

As illustrated in FIGS. 2A and 2B, layer D0L is formed over the base layer BL (if the base layer BL includes B0L and C0L, the layer D0L is formed over the second layer C0L). The layer D0L is structured based on alignment information from the first sub-structure of the hybrid alignment mark (formed by lithography B0) and alignment information from the second sub-structure of the hybrid alignment mark (formed by lithography C0). Therefore, lithography D0 uses alignment information of lithography B0 and of lithography C0.

The base layer BL (or, if composed of first and second layers B0L and C0L, the first layer B0L) may, e.g., be aligned to layer A0L. However, the layer A0L is optional. It may also be the case that the base layer BL is formed by the bulk body of the semiconductor substrate. In this case, the first lithography process B0 is used to process the bulk body of the semiconductor substrate and the second lithography process C0 may also be used to process the bulk body of the semiconductor substrate. If the base layer BL includes the first layer B0L and the second layer C0L, the first layer B0L may, e.g., be the bulk body of the semiconductor substrate and the second layer C0L may, e.g., be any layer disposed over layer B0L, for example an epitaxial layer or a polysilicon layer, etc. In this case, the first lithography process B0 may be used to process the bulk body of the semiconductor substrate and the second lithography process C0 may be used to process the layer C0L.

As mentioned before, functional structures in the first layer B0L may, e.g., include trenches, and functional structures in the second layer C0L may, e.g., include polysilicon structures. In other examples, the functional structures in the second layer C0L may (also) include trenches. In this case, the trenches in layer C0L may be of different type than the trenches in layer B0L. For example, the trenches in layer B0L may be stripe-shaped trenches while the trenches in layer C0L may be needle trenches.

As mentioned before, functional structures in the layer D0L may, e.g., implement contacts to the functional structures in the second layer C0L and contacts to the functional structures in the first layer B0L. As lithography D0 is aligned to lithography B0 and lithography C0, the functional structures in layer D0L become aligned by best compromise to the (first) functional structures in the first layer B0L (or in the base layer BL) and the (second) functional structures in the second layer C0L (or in the base layer BL). That way, a worst case misalignment of any of these functional structures can be excluded.

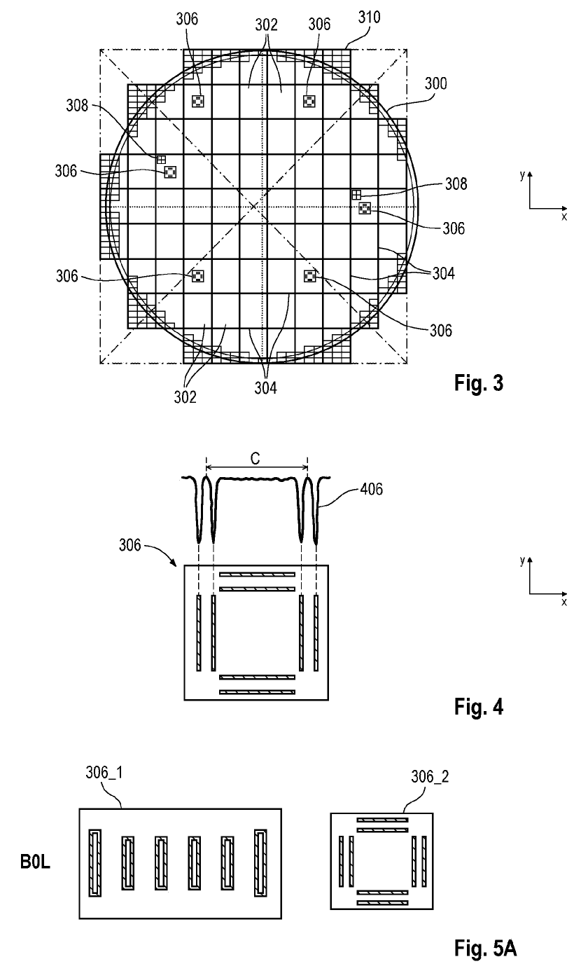

FIG. 3 illustrates the top surface of a semiconductor substrate 300, e.g. a wafer. The semiconductor substrate 300 includes a plurality of device regions 302, which may be arranged in a regular array of rows and columns. Scribelines 304 may extend parallel to one another in, e.g., the X direction and in the Y direction to form a grid.

The semiconductor substrate 300 further includes at least one alignment mark 306. In the example shown, six alignment marks 306 are distributed over the semiconductor substrate 300. Conventionally, they are all produced by the same reticle. The alignment marks 306 are also referred to as fine alignment marks in the art. In accordance with the disclosure, the alignment marks 306 are hybrid alignment marks.

The semiconductor substrate 300 may further include pre-alignment marks 308, e.g. TVPA marks. They are used for pre-alignment of the semiconductor substrate 300.

FIG. 3 further illustrates, by way of example, a circumferential part of a stepping grid 310 used by a lithography exposure tool (e.g. a stepper or a scanner) during the exposure process. The stepping grid 310 is calculated based on grid information obtained from the alignment marks 306, as will be described in more detail further below.

Using the conventional alignment scheme as shown in FIGS. 1A and 1B, the exposure tool for the lithography process D0 will not take into account how the second layer C0L was aligned relative to the first layer B0L. Therefore, as illustrated in FIG. 1A, misalignment between the layer D0L and the second layer C0L may be greater than the alignment tolerances for direct alignment (solid arrows in FIG. 1A).

FIG. 4 illustrates a geometric pattern of an example of an alignment mark 306. The alignment mark 306 is a two-dimensional alignment mark which provides information about alignment in the X direction and in the Y direction. The alignment mark 306 is generated (e.g. etched) in the semiconductor substrate 300 based on a lithography process by which a resist mask is structured and then used, for example, as an etch mask for the alignment mark 306 and the corresponding functional structure(s).

The positional information of the alignment mark 306 is extracted by way of optical recognition. For example, a contrast-based recognition of the mark pattern may be used to provide a signal (so-called mark waveform) 406. Optical mark pattern recognition may, e.g., be performed by a CCD (charge-coupled device) camera.

The signal 406 may then be evaluated to obtain a center position of the alignment mark 306. The center position is dependent on the mark pattern extending in X direction and on the mark pattern extending in Y direction.

For example, the center position in X direction may be determined by the center point of the distance C between signal peaks as shown in FIG. 4. The center position in Y direction may be obtained analogously by determining the center point of a distance C between signal peaks (not shown) in Y direction.

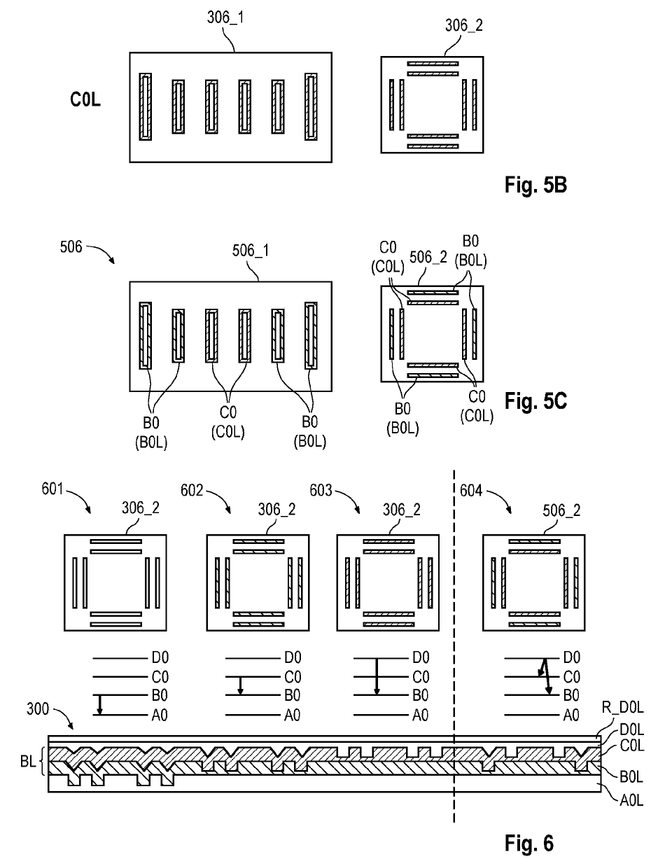

FIG. 5A illustrates an example of a bar alignment mark 306_1 and an example of a XY alignment mark 306_2 typically used in image-processing based alignment technology, for example FIA (field image alignment) technology and/or AGA (advanced global alignment) technology. For example, the bar alignment mark 306_1 is referred to as a 20P-4FA mark and the XY alignment mark 306_2 is referred to as a XY4 mark. Obviously, the bar alignment mark 306_1 only allow to determine the center position in one direction (e.g. the X direction) while the XY alignment mark 306_2 allows to obtain the center position of the XY alignment mark 306_2 in the two directions X, Y by using only one mark image.

FIG. 5A illustrates the conventional approach in which the alignment marks 306_1, 306_2 are formed in one layer, e.g. in layer B0L.

FIG. 5B illustrates a top view on another layer, in this example on layer C0L. Again, the conventional approach is shown in which the alignment marks 306_1, 306_2 are formed in only one layer (her layer C0L, for example).

In FIGS. 5A and 5B the hatched geometric pattern are structured (etched) portions of the respective layer B0L and C0L. For purpose of illustration, the direction of hatching refers to the respective layer.

FIG. 5C illustrates a top view on (hybrid) alignment marks 506 in accordance with the disclosure, namely a bar alignment mark 506_1 and a XY alignment mark 506_2. The alignment marks 506 include a first substructure formed by a first mask-and-exposure lithography process (here exemplified by B0) and a second sub-structure formed by a second mask-and-exposure lithography process (here exemplified by C0).

For example, in bar alignment mark 506_1, the pairs of outer bars (first sub-structure) may, e.g., be formed by lithography process B0. The two inner bars (second sub-structure) may, e.g., be formed by lithography process C0.

In XY alignment mark 506_2, the outer sectional square pattern (first sub-structure) may, e.g., be formed by lithography process B0. The inner sectional square pattern (second sub-structure) may, e.g., be formed by lithography process C0.

As mentioned before, the two lithography processes may, e.g., be applied to the same layer referred to as base layer BL in FIG. 2B. However, it is also possible that the base layer BL includes two layers of different material, namely layer B0L and layer C0L, for example. In this case, the lithography process B0 is used to structure (etch) the first layer B0L and the lithography process C0 is used to structure (etch) the second layer C0L.

FIG. 6 illustrates an example of an alignment scheme wherein two lithography processes (e.g. B0 and C0) are used to generate conventional alignment marks (left side of dashed line) and a (hybrid) alignment mark (right side of dashed line) in accordance with the disclosure.

At reference sign 601, a standard alignment mark 306, e.g. XY alignment mark 306_2, is generated by lithography A0 and etched into layer A0L, e.g. the bulk semiconductor material of the semiconductor substrate 300.

During subsequent processing steps, the recesses of the mark pattern in the layer A0L are (partially) filled by the material of the first layer B0L. For example, the first layer B0L may be an epitaxia1 layer of doped silicon.

At reference sign 602, a standard alignment mark 306 (here: XY alignment mark 306_2) is generated by lithography B0 and etched into the first layer B0L. The lithography B0 is aligned with the alignment mark 306_2 in layer A0L. The recesses of the alignment mark in layer B0L are (partially) filled by deposition of the material of the second layer C0L. The second layer C0L may, e.g., be a polysilicon layer, for example.

At reference sign 603, an alignment mark 306 (here: XY alignment mark 306_2) is generated by lithography C0 and etched into the second layer C0L (e.g., polysilicon). The lithography C0 is aligned to the alignment mark 306_2 in the first layer B0L. The recesses produced in the second layer C0L may then be (partially) filled by deposition of the material of the layer D0L (e.g. metal). In FIG. 6, the layer D0L has then be subjected to a chemical mechanical polishing (CMP) process, for example.

Subsequently, a resist layer R_D0L for D0 lithography may be formed over the (unstructured) layer D0L. The exposure of the resist layer R_D0L and thus the following structuring of the layer D0L may be aligned to the align-to lithography B0 (i.e. to the align-to layer B0L).

The hybrid alignment mark 506 (here: XY alignment mark 506_2, for example) is formed by lithography B0 and lithography C0 in the first layer B0L and the second layer C0L, respectively (compare FIG. 5C). As mentioned before, the alignment mark 506_2 does not need to be formed in two different layers B0L and C0L, but may alternatively be formed in a single common base layer BL by two lithography processes B0 and C0. Subsequently, a resist layer R_D0L for D0 lithography may be formed over the (unstructured) layer D0L. The exposure of the resist layer R_D0L and thus the following structuring of the layer D0L may be aligned to the “align-to” lithography B0 and C0 (e.g., to the “align-to” layers B0L and C0L).

FIG. 6 is a simplified and schematic illustration of possible layers participating in the hybrid alignment mark formation. A variety of different options for materials, layer stacks and combinations thereof can be used. In addition, further layers and processing steps may be used between the shown exemplary layers A0L, B0L, C0L, D0L and R_D0L.

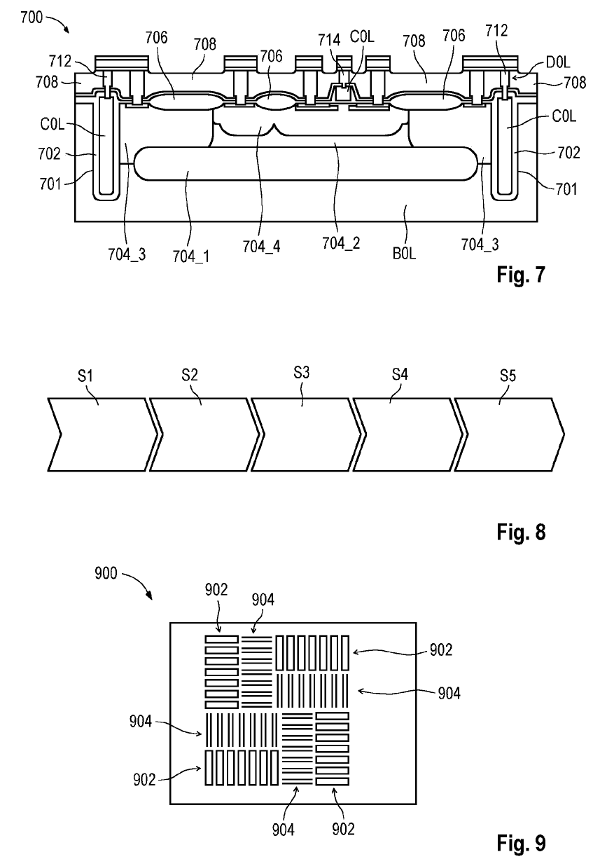

FIG. 7 illustrates an exemplary semiconductor device, e.g. a transistor. In this example, the bulk body of the semiconductor device 700 (corresponding to the bulk body of the semiconductor substrate 300) is formed by the first layer B0L. The first layer B0L includes trenches 701. The trenches 701 form first functional structures of the semiconductor device 700.

The trenches are filled by polysilicon of the second layer C0L, which is electrically insulated by a trench oxide 702 against the bulk body B0L. The polysilicon may form second functional structures of the semiconductor device 700.

A contact layer D0L is disposed over the second layer C0L. As apparent from FIG. 7, vertical contacts 712, 714 of the contact layer D0L need to be aligned both to the polysilicon structures of the second layer C0L and to the trenches of the first layer B0L. Optimum alignment to these two layers is achieved by providing the hybrid alignment mark 506 in both layers B0L and C0L so that for lithography D0, two “align-to” layers B0L and C0L are effective. In the example shown, the vertical contact 714 forms a poly contact, while the vertical contacts 712 form trench contacts.

The exemplary semiconductor device 700 may further include implant regions 704_1, 704_2, 704_3, 704_4, LOCOS (LOCal Oxidation of Silicon) regions 706, and an intermediate oxide 708, for example. Without saying, many other designs of the semiconductor device 700 are possible.

FIG. 8 illustrates exemplary stages of a process flow for manufacturing a semiconductor substrate 300, e.g. semiconductor device 700. The process flow may start at S1 with a pre-alignment stage. Pre-alignment is based on the TVPA pre-alignment marks 308.

Subsequently, at S2, fine alignment is performed. Fine alignment relies on optically evaluating the positions of the (hybrid) fine alignment marks 506.

At S3, a set of substrate geometry parameters (also referred to as grid parameters or wafer parameters) are calculated based on the alignment information from the hybrid alignment mark 506. The calculation of the set of substrate parameters may be performed without a-priory knowledge about which sub-structure of the alignment mark is from lithography B0 and which sub-structure of the alignment mark 506 is from lithography C0. In other words, the optical recognition of the alignment mark 506 to provide a signal based on the contrast of the alignment mark and the evaluation of the signal to obtain a center position of the alignment mark 506 may be carried out in the same way as it is conventionally done for this type of alignment mark 306_1, 306_2. In particular, the evaluation of the signal may be performed independently of any information which part of the pattern of the alignment mark 506 is the first sub-structure (produced by lithography B0) and which part of the pattern is the second sub-structure (produced by lithography C0).

That way, the calculation of the set of substrate geometry parameters uses a “best-compromise” approach, i.e. any misalignment between lithography B0 and lithography C0 is automatically compensated as best as possible for lithography D0.

The set of substrate geometry parameters calculated, e.g., by the exposure tool may comprise one or of a substrate translation X, a substrate translation Y, a substrate rotation X, a substrate rotation Y, a substrate magnification X and a substrate magnification Y. X and Y are different lateral directions within a plane defined by the semiconductor substrate 300.

At S4 a step-by-step exposure by an exposure tool (stepper or scanner, for example) is performed. The step-by-step exposure may be based on “auto-compensated” substrate geometry parameters calculated at S3. Auto-compensation is performed by the exposure tool based on “auto-compensated” substrate geometry parameters.

At S4, one or a plurality of lithography processes may be carried out. For example, S4 may involve lithography B0, lithography C0 and lithography D0. As mentioned before, a plurality of layer deposition processes may be performed between the lithography processes, for example, the deposition of layers B0L, C0L (or, only a single layer BL) and layer D0L.

At S5, an overlay (OV) measurement is performed. OV measurements are used to determine overlay errors between individual pairs of layers. For example, S5 may include an OV measurement between layers D0L and B0L. Further, S5 may include an OV measurement between layers D0L and C0L.

OV measurements are based on determining and evaluating the positions of a primary overlay measurement mark formed in a first layer and a secondary overlay measurement mark formed in a second layer. For example, if the overlay error is measured between layers D0L and B0L, the layer B0L may include the primary overlay measurement mark and the layer D0L may include the secondary overlay measurement mark. These overlay measurement marks were generated by lithography B0 and lithography D0, respectively. The evaluation of the position of the overlay measurement marks is similar to the evaluation of the position of the alignment marks 306 described above.

FIG. 9 illustrates a top view on a pattern 900 of a primary overlay measurement mark and a secondary overlay measurement mark. The primary overlay measurement mark, which may, e.g., be formed in the bulk body of a substrate 300 and/or in layer A0L of the substrate 300, includes outer comb-like structures 902. The secondary overlay measurement mark formed in another layer, e.g. in a patterned resist layer R_D0L (see FIG. 6) for lithography D0 on layer D0L, is formed by inner comb-like structures 904. The pattern 900 of primary and secondary overlay measurement marks is known as an AIM (Advanced Imaging Metrology) type overlay measurement mark.

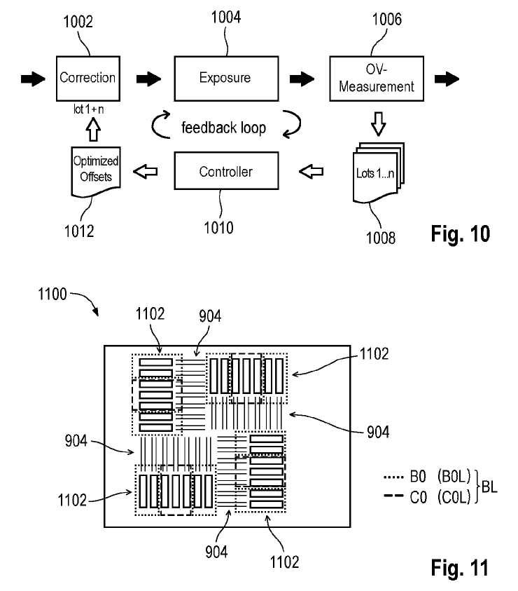

FIG. 10 schematically illustrates a process flow including an overlay feedback control loop for stabilizing the overlay error during manufacturing of a plurality of semiconductor substrates (wafers) 300. Overlay error stabilizing (minimizing) is done by correcting one or more of the set of substrate geometry parameters by a respective overlay error parameter to obtain a set of corrected substrate geometry parameters at 1002. The overlay error parameters are derived after exposure at 1004 by an overlay measurement 1006, as described above.

The overlay measurement 1006 may be performed substrate-to-substrate or selectively for only some of the substrates. Principally, the corresponding overlay error parameters could be used to calculate the set of corrected substrate geometry parameters for the next semiconductor substrate to be processed. However, in some feedback loops for overlay measurement 1006, substrate geometry parameter correction is performed lot-to-lot (a lot 1008 includes n semiconductor substrates, wherein n is an integer greater than 1, e.g. n = 25±5, for example). That is, overlay error parameters for a lot of semiconductor substrates 300 (which may be obtained by OV measurements of only a part or all of the substrates of the lot) are used as alignment offsets 1012. The controller 1010 outputs the (optimized) alignment offsets, which are then applied by the lithography exposure tool at 1002 and 1004.

According to a further aspect of the disclosure, the concept of using two “align-to” lithography processes (and optionally two layers on which these lithography processes are applied) for forming a (hybrid) alignment mark 506 may be analogously applied to OV measurement marks.

FIG. 11 illustrates a pattern 1100 of such (hybrid) overlay measurement mark. Similar to the pattern 900 of a conventional overlay measurement mark, the pattern 1100 includes inner comb-like structures 904 of, e.g., a patterned resist layer R_D0L, which is exposed and developed and intended to be used for structuring a layer (e.g. D0L) by lithography D0.

The outer comb-like structures 1102 correspond to the outer comb-like structures 902 of the conventional overlay measurement pattern 900, i.e. to the primary overlay measurement mark. However, two lithography processes and, optionally, two layers are involved. More specifically, the sub-structure encircled by dotted lines may, e.g., be produced by lithography B0 in “align-to” layer B0L or base layer BL and the sub-structure encircled by dashed lines may be produced by lithography C0 in “align-to” layer C0L or (also) in the base layer BL. That way, the overlay error per semiconductor substrate 300 and/or the mean overlay error for a lot 1008 (or a subset of the lot) of semiconductor substrates 300 may be calculated based on the best compromise for minimizing an alignment error to both earlier lithography processes B0 and C0. The term overlay error parameter as used herein can have the meaning of overlay error parameters for a specific semiconductor substrate 300 or mean overlay error parameters derived by averaging overlay error parameters obtained by OV measurements of a plurality of semiconductor substrates 300.

Analogously to the optical recognition and signal evaluation of the (hybrid) alignment marks 306, the pattern 1100 including the primary overlay measurement mark (outer comb-like structures 1102) and the secondary overlay measurement mark (inner comb-like structures 904) may be optically recognized to provide a first signal based on the contrast of the primary overlay measurement mark and a second signal based on the contrast of the secondary overlay measurement mark (inner comb-like structures 904). The first signal and the second signal are evaluated to obtain the set of overlay error parameters.

The evaluation of the first signal (which includes information about two lithography processes B0 and C0) may use a “best-compromise” approach. That is, the evaluation of the first signal may be done the same way as with a conventional OV measurement mark pattern 900. In particular, the first signal may be evaluated without a-priory knowledge about the potential misalignment between the first sub-structure (encircled by doted lines) of the primary overlay measurement mark and the second sub-structure (encircled by dashed lines) of the primary overlay measurement mark.

The evaluation of the second signal formed by the inner comb-like structures 904 may (also) be carried out the same way as for the pattern 900 of a conventional overlay measurement mark.

The set of overlay error parameters may comprise one or more of an overlay error translation X, an overlay error translation Y, an overlay error rotation X, an overlay error rotation Y, an overlay error magnification X and an overlay error magnification Y. The (mean) overlay error parameters may be used as alignment offsets for correction 1002 of the substrate geometry parameters, as explained above. In this case, the process flow of FIG. 10 may, e.g., include “best compromise” overlay error parameter calculation by using hybrid OV measurement marks 1100. Further, it may use auto-compensation of the alignment process (by using hybrid alignment marks 506 as described above, i.e. based on the “best compromise” overlay error parameter).

The following examples pertain to further aspects of the disclosure.

Example 1 is a semiconductor substrate which comprises an alignment mark. The semiconductor substrate comprises a base layer. The base layer comprises a first sub-structure of the alignment mark and a second sub-structure of the alignment mark. The first sub-structure is formed by a first mask-and-exposure lithography process and the second sub-structure is formed by a second mask-and-exposure lithography process. The semiconductor substrate further comprises a structured layer disposed over the base layer, wherein the first sub-structure and the second sub-structure are configured to provide alignment information for alignment of the structured layer.

In Example 2, the subject matter of Example 1 can optionally include wherein the first sub-structure and the second sub-structure form a geometric pattern that forms the alignment mark.

In Example 3, the subject matter of Example 1 or 2 can optionally include wherein the base layer comprises a first functional structure generated within the first mask-and-exposure lithography process together with the first sub-structure and a second functional structure generated within the second mask-and-exposure lithography process together with the second sub-structure, and the structured layer comprises a third functional structure aligned with the first functional structure and the second functional structure.

In Example 4, the subject matter of Example 3 can optionally include wherein the first functional structure comprises trenches of a first type and/or the second functional structure comprises polysilicon structures and/or trenches of a second type.

In Example 5, the subject matter of Example 3 or 4 can optionally include wherein the third functional structure comprises first contact holes and second contact holes, wherein the first contact holes connect to the first functional structure, in particular trenches of a first type, and the second contact holes connect to the second functional structure, in particular polysilicon contacts and/or trenches of a second type.

In Example 6, the subject matter of any of the preceding Examples can optionally include wherein the base layer comprises a first layer, the first layer comprising the first sub-structure of the alignment mark, and a second layer disposed over the first layer, the second layer comprising the second sub-structure of the alignment mark.

In Example 7, the subject matter of Example 6 can optionally include wherein the first layer comprises the first functional structure and the second layer comprises the second functional structure.

In Example 8, the subject matter of any of the preceding Examples can optionally include wherein the alignment mark is a mark configured to be used by a lithography exposure tool, in particular a stepper or a scanner during alignment.

Example 9 is a method of manufacturing a semiconductor substrate comprising an alignment mark. The method comprises forming a first sub-structure of the alignment mark in a base layer of the semiconductor substrate by a first mask-and-exposure lithography process. A second sub-structure of the alignment mark in the base layer is formed by a second mask-and-exposure lithography process. A layer is formed over the base layer. The layer is structured based on alignment information from the first sub-structure and alignment information from the second sub-structure.

In Example 10, the subject matter of Example 9 can optionally include forming a first layer of the base layer, wherein the first sub-structure of the alignment mark is formed in the first layer; and forming a second layer of the base layer over the first layer, wherein the second sub-structure of the alignment mark is formed in the second layer.

In Example 11, the subject matter of Example 9 or 10 can optionally further include calculating a set of substrate geometry parameters based on the alignment information from the first sub-structure and the alignment information from the second sub-structure; and wherein structuring the layer comprises exposing the layer by a lithography exposure tool based on the set of substrate geometry parameters.

In Example 12, the subject matter of Example 11 can optionally include wherein calculating the set of substrate geometry parameters comprises optically recognizing the alignment mark to provide a signal based on the contrast of the alignment mark; and evaluating the signal to obtain a center position of the alignment mark, wherein the center position is dependent on alignment information from the first sub-structure and alignment information from the second sub-structure.

In Example 13, the subject matter of Example 12 can optionally include wherein the calculation of the set of substrate geometry parameters is performed without a-priory knowledge of which input of the calculation is based on the alignment information from the first sub-structure and which input of the calculation is based on the alignment information from the second sub-structure.

In Example 14, the subject matter of any of the Examples 11 to 13 can optionally include wherein the set of substrate geometry parameters comprises one or more of a substrate translation X, a substrate translation Y, a substrate rotation X, a substrate rotation Y, a substrate magnification X, a substrate magnification Y, wherein X and Y are different lateral directions within a plane defined by the semiconductor substrate.

In Example 15, the subject matter of any of the Examples 11 to 14 can optionally include wherein, when manufacturing a plurality of semiconductor substrates, the substrate geometry parameters are recalculated for each semiconductor substrate.

In Example 16, the subject matter of any of the Examples 11 to 15 can optionally include wherein, when manufacturing a plurality of semiconductor substrates before manufacturing the semiconductor substrate, performing, for at least some of the plurality of semiconductor substrates, an overlay error measurement for calculating a set of overlay error parameters relating to an overlay error between the base layer and the third layer or, if the base layer comprises a first layer having the first sub-structure and a second layer having the second sub-structure, to an overlay error between two of the first layer, the second layer and the third layer of the respective semiconductor substrate, and wherein structuring the layer of the semiconductor substrate is additionally based on the set of overlay error parameters.

In Example 17, the subject matter of the Example 16 can optionally include wherein the set of overlay error parameters comprises one or more of an overlay error translation X, an overlay error translation Y, an overlay error rotation X, an overlay error rotation Y, an overlay error magnification X, an overlay error magnification Y, wherein X and Y are different lateral directions within a plane defined by the semiconductor substrate.

In Example 18, the subject matter of the Example 17 can optionally include wherein structuring the layer of the semiconductor substrate comprises: correcting one or more of the set of substrate geometry parameters by the respective overlay error parameter to obtain a set of corrected substrate geometry parameters, and structuring the layer of the semiconductor substrate based on the set of corrected substrate geometry parameters.

Example 19 is a semiconductor substrate comprising a primary overlay measurement mark and a secondary overlay measurement mark. The semiconductor substrate comprises a base layer, the base layer comprising a first sub-structure of the primary overlay measurement mark and a second sub-structure of the primary overlay measurement mark, the first sub-structure being formed by a first mask-and-exposure lithography process and the second sub-structure being formed by a second mask-and-exposure lithography process; and a structured layer disposed over the base layer, the structured layer comprising the secondary overlay measurement mark.

In Example 20, the subject matter of Example 19 can optionally further include wherein the base layer comprises a first layer, the first layer comprising the first sub-structure of the primary overlay measurement mark; and a second layer disposed over the first layer, the second layer comprising the second sub-structure of the primary overlay measurement mark.

In Example 21, the subject matter of Example 19 or 20 can optionally include wherein the base layer comprises a first layer, the first layer comprising the first sub-structure of the primary overlay measurement mark; and a second layer disposed over the first layer, the second layer comprising the second sub-structure of the primary overlay measurement mark.

In Example 22, the subject matter of any of Examples 19 to 21 can optionally include wherein the primary overlay measurement mark is a mark configured to be used, together with the secondary overlay measurement mark, by an overlay measurement tool during overlay error measurement.

Example 23 is a method of performing an overlay error measurement on a semiconductor substrate, which comprises a primary overlay measurement mark and a secondary overlay measurement mark. The method comprises forming a first sub-structure of the primary overlay measurement mark in a base layer of the semiconductor substrate by a first mask-and-exposure lithography process. A second sub-structure of the primary overlay measurement mark is formed in the base layer by a second mask-and-exposure lithography process. A layer is formed over the base layer, the layer comprising the secondary overlay measurement mark. The primary overlay measurement mark and the secondary overlay measurement mark are optically recognized to provide a first signal based on the contrast of the primary overlay measurement mark and a second signal based on the contrast of the secondary overlay measurement mark. The first signal and the second signal are evaluating to obtain a set of optimized offset parameters.

In Example 24, the subject matter of Example 23 can optionally further include forming a first layer of the base layer, the first layer comprising the first sub-structure of the primary overlay measurement mark; and forming a second layer of the base layer over the first layer, the second layer comprising the second sub-structure of the primary overlay measurement mark.

In Example 25, the subject matter of Example 24 can optionally further include wherein the set of optimized offset parameters comprises one or more of an overlay error translation X, an overlay error translation Y, an overlay error rotation X, an overlay error rotation Y, an overlay error magnification X, an overlay error magnification Y, wherein X and Y are different lateral directions within a plane defined by the semiconductor substrate.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor substrate, comprising:
an alignment mark;
a base layer, the base layer comprising a first sub-structure of the alignment mark and a second sub-structure of the alignment mark, the first sub-structure being formed by a first mask-and-exposure lithography process and the second sub-structure being formed by a second mask-and-exposure lithography process; and
a structured layer disposed over the base layer,
wherein the first sub-structure and the second sub-structure are configured to provide alignment information for alignment of the structured layer.

2. The semiconductor substrate of claim 1, wherein the first sub-structure and the second sub-structure form a geometric pattern that forms the alignment mark.

3. The semiconductor substrate of claim 1, wherein:
the base layer further comprises a first functional structure generated within the first mask-and-exposure lithography process together with the first sub-structure, and a second functional structure generated within the second mask-and-exposure lithography process together with the second sub-structure; and
the structured layer comprises a third functional structure aligned with the first functional structure and the second functional structure.

4. The semiconductor substrate of claim 3, wherein:
the first functional structure comprises trenches of a first type; and/or
the second functional structure comprises polysilicon structures and/or trenches of a second type.

5. The semiconductor substrate of claim 3, wherein:
the third functional structure comprises first contact holes and second contact holes;
the first contact holes connect to trenches of a first type;
the second contact holes connect to polysilicon structures and/or trenches of a second type.

6. The semiconductor substrate of claim 1, wherein the base layer further comprises:
a first layer, the first layer comprising the first sub-structure of the alignment mark; and
a second layer disposed over the first layer, the second layer comprising the second sub-structure of the alignment mark.

7. The semiconductor substrate of claim 6, wherein the first layer comprises a first functional structure generated within the first mask-and-exposure lithography process together with the first sub-structure, and the second layer comprises a second functional structure generated within the second mask-and-exposure lithography process together with the second sub-structure.

8. The semiconductor substrate of claim 1, wherein the alignment mark is a mark configured to be used by a lithography exposure tool during alignment.

9. A method of manufacturing a semiconductor substrate comprising an alignment mark, the method comprising:
forming a first sub-structure of the alignment mark in a base layer of the semiconductor substrate by a first mask-and-exposure lithography process;
forming a second sub-structure of the alignment mark in the base layer by a second mask-and-exposure lithography process;
forming a layer over the base layer; and
structuring the layer based on alignment information from the first sub-structure and alignment information from the second sub-structure.

10. The method of claim 9, further comprising:
forming a first layer of the base layer, wherein the first sub-structure of the alignment mark is formed in the first layer; and
forming a second layer of the base layer over the first layer, wherein the second sub-structure of the alignment mark is formed in the second layer.

11. The method of claim 9, further comprising:
calculating a set of substrate geometry parameters based on the alignment information from the first sub-structure and the alignment information from the second sub-structure, and
wherein structuring the layer comprises exposing the layer by a lithography exposure tool based on the set of substrate geometry parameters.

12. The method of claim 11, wherein calculating the set of substrate geometry parameters comprises:
optically recognizing the alignment mark to provide a signal based on the contrast of the alignment mark; and
evaluating the signal to obtain a center position of the alignment mark, wherein the center position is dependent on alignment information from the first sub-structure and alignment information from the second sub-structure.

13. The method of claim 12, wherein the calculation of the set of substrate geometry parameters is performed without a-priory knowledge of which input of the calculation is based on the alignment information from the first sub-structure and which input of the calculation is based on the alignment information from the second sub-structure.

14. The method of claim 11, wherein the set of substrate geometry parameters comprises one or more of a substrate translation X, a substrate translation Y, a substrate rotation X, a substrate rotation Y, a substrate magnification X, and a substrate magnification Y, and wherein X and Y are different lateral directions within a plane defined by the semiconductor substrate.

15. The method of claim 11, wherein when manufacturing a plurality of semiconductor substrates, the substrate geometry parameters are recalculated for each semiconductor substrate.

16. The method of claim 11, wherein when manufacturing a plurality of semiconductor substrates before manufacturing the semiconductor substrate, performing, for at least some of the plurality of semiconductor substrates, an overlay error measurement for calculating a set of overlay error parameters relating to an overlay error between the base layer and the third layer or, if the base layer comprises a first layer having the first sub-structure and a second layer having the second sub-structure, to an overlay error between two of the first layer, the second layer and the third layer of the respective semiconductor substrate, and wherein structuring the layer of the semiconductor substrate is additionally based on the set of overlay error parameters.

17. The method of claim 16, wherein the set of overlay error parameters comprises one or more of an overlay error translation X, an overlay error translation Y, an overlay error rotation X, an overlay error rotation Y, an overlay error magnification X, and an overlay error magnification Y, and wherein X and Y are different lateral directions within a plane defined by the semiconductor substrate.

18. The method of claim 17, wherein structuring the layer of the semiconductor substrate comprises:
correcting one or more of the substrate geometry parameters by the respective overlay error parameter to obtain a set of corrected substrate geometry parameters; and
structuring the layer of the semiconductor substrate based on the set of corrected substrate geometry parameters.

19. A semiconductor substrate, comprising:
a primary overlay measurement mark;
a secondary overlay measurement mark;
a base layer, the base layer comprising a first sub-structure of the primary overlay measurement mark and a second sub-structure of the primary overlay measurement mark, the first sub-structure being formed by a first mask-and-exposure lithography process and the second sub-structure being formed by a second mask-and-exposure lithography process; and
a structured layer disposed over the base layer, the structured layer comprising the secondary overlay measurement mark.

20. The semiconductor substrate of claim 19, wherein the base layer further comprises:
a first layer, the first layer comprising the first sub-structure of the primary overlay measurement mark; and
a second layer disposed over the first layer, the second layer comprising the second sub-structure of the primary overlay measurement mark.

21. The semiconductor substrate of claim 19, wherein the first sub-structure and the second sub-structure form a geometric pattern that forms the primary overlay measurement mark.

22. The semiconductor substrate of claim 19, wherein the primary overlay measurement mark is a mark configured to be used, together with the secondary overlay measurement mark, by an overlay measurement tool during overlay error measurement.

23. A method of performing an overlay error measurement on a semiconductor substrate comprising a primary overlay measurement mark and a secondary overlay measurement mark, the method comprising:
forming a first sub-structure of the primary overlay measurement mark in a base layer of the semiconductor substrate by a first mask-and-exposure lithography process;
forming a second sub-structure of the primary overlay measurement mark in the base layer by a second mask-and-exposure lithography process;
forming a layer over the base layer, the layer comprising the secondary overlay measurement mark;
optically recognizing the primary overlay measurement mark and the secondary overlay measurement mark to provide a first signal based on the contrast of the primary overlay measurement mark and a second signal based on the contrast of the secondary overlay measurement mark; and
evaluating the first signal and the second signal to obtain a set of overlay error parameters.

24. The method of claim 23, further comprising:
forming a first layer of the base layer, the first layer comprising the first sub-structure of the primary overlay measurement mark; and
forming a second layer of the base layer over the first layer, the second layer comprising the second sub-structure of the primary overlay measurement mark.

25. The method of claim 24, wherein the set of overlay error parameters comprises one or more of an overlay error translation X, an overlay error translation Y, an overlay error rotation X, an overlay error rotation Y, an overlay error magnification X, and an overlay error magnification Y, and wherein X and Y are different lateral directions within a plane defined by the semiconductor substrate.
